(19) United States
(12) Patent Application Publication
(10) Pub. No.: US 2007/0205490 A1
(43) Pub. Date: Sep. 6, 2007

(54) Method for Production of Semiconductor Chip, and Semiconductor Chip

(75) Inventor: Katsuki Kusunoki, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 10/581,335

(22) PCT Filed: Dec. 2, 2004
(86) PCT No.: PCT/JP04/18325

§ 371 Date: Dec. 14, 2006

Related U.S. Application Data
(60) Provisional application No. 60/534,193, filed on Jan. 2, 2004.

(30) Foreign Application Priority Data
Dec. 5, 2003 (JP) 2003-407550

(51) Int. Cl. H01L 21/301

(52) U.S. Cl. 257/620; 438/462; 257/E31.001

(57) ABSTRACT

A method for the production of gallium nitride compound semiconductor chips from a wafer having gallium nitride compound semiconductor layers (2, 3) laminated on the principal surface of a substrate (1) comprises a step of forming first grooves (11) linearly in a desired chip shape by etching on the gallium nitride compound semiconductor layers (2, 3) sides of the wafer, a step of forming second grooves (22) having a nearly equal or smaller line width (W2) than a line width (W1) of the first grooves on the substrate (1) side of the wafer at positions not conforming to the central lines of the first grooves, and a step of dividing the wafer along the first and second grooves. It consequently allows the wafer to be accurately cut in an extremely high yield, with the result that the number of chips taken out of one wafer will be increased and the productivity will be enhanced.

### CROSS REFERENCE TO RELATED APPLICATIONS

This application is an application filed under 35 U.S.C. §111(a) claiming the benefit pursuant to 35 U.S.C. §119(e)(1) of the filing date of Provisional Application No. 60/534,193 filed Jan. 2, 2004 pursuant to 35 U.S.C. §111(b).

### TECHNICAL FIELD

This invention relates to a method for the production of a semiconductor chip directed toward producing a gallium nitride compound semiconductor chip for use in light emitting devices, such as a blue-color light-emitting diode and a blue-color laser diode, and to semiconductor chips produced by the method of production.

### BACKGROUND ART

A scriber or a dicer has been hitherto used in cutting chips for use in light-emitting devices from a wafer which results from lamination of semiconductor materials.

Incidentally, when the semiconductor material happens to be a nitride, the nitride semiconductor is generally laminated on a wafer which is formed of a sapphire substrate. Since this wafer does not possess cleavability by the nature of the sapphire crystal forming a hexagonal system, it is not easily cut with a scriber.

When a sapphire substrate and a nitride semiconductor which are both extremely hard substances are to be cut with a dicer, the cut faces are liable to form cracks and chippings. The sapphire substrate and the nitride semiconductor have a large mismatching of lattice constants and a wide difference of thermal expansion coefficients owing to their heteroepitaxial structure. When they are cut with a dice, therefore, the problem arises that the nitride semiconductor layer is rendered easily separable from the sapphire substrate.

For the purpose of solving the conventional technical problem mentioned above, the method disclosed in Japanese Patent No. 2780618 has been proposed as another method for cutting nitride semiconductor chips for use in light-emitting devices from a wafer. This method, in cutting a wafer resulting from forming a gallium nitride compound semiconductor layer 200 on a sapphire substrate 100 as shown in FIG. 4, enables chips of required shape and size to be cut by forming first grooves 110 on the gallium nitride compound semiconductor layer 200 side and forming second grooves 220 having a thinner line width (W20) than the line width (W10) of the first grooves 110 at positions conforming to the central lines of the grooves 110 on the sapphire substrate 100 side.

When the method of the Japanese Patent mentioned above is actually put to practice, during the separation of chips, only few chip sections are broken along the central line f of the first grooves 110 and most chip sections are broken diagonally along broken lines d and e. Thus, it has been found that these broken faces enter into the gallium nitride compound semiconductor layer 200 and turn the produced chips into rejected articles, with the result that the yield of chips will decline. Further, since the chip sections are diagonalized, the method entails such problems as rendering production of chips in a smaller size difficult, imposing a limit on the number of chips taken out of one wafer and deteriorating productivity.

This invention has been proposed in view of the state of affairs mentioned above and is aimed at providing a method for the production of gallium nitride compound semiconductor chips which is capable of cutting chips accurately in an extremely high yield, increasing the number of semiconductor chips to be taken out of one wafer and enhancing productivity, and also providing semiconductor chips obtained by the method of production.

### DISCLOSURE OF THE INVENTION

With a view to accomplishing the object mentioned above, this invention provides a method for the production of gallium nitride compound semiconductor chips from a wafer having gallium nitride compound semiconductor layers laminated on a principal surface of a substrate, which comprises a step of linearly forming first grooves of a desired chip shape by etching on a side of the gallium nitride compound semiconductor layer of the wafer, a step of forming second grooves having a nearly equal or smaller line width (W2) than a line width (W1) of the first grooves on a side of the substrate of the wafer at positions not conforming to central lines of the first grooves, and a step of dividing the wafer into pieces each of a chip shape.

The method according to this invention for the production of semiconductor chips embraces forming the substrate of sapphire, with a C surface of the sapphire substrate as the principal surface, forming the first and second grooves respectively along a first direction parallel to an orientation flat (11-20) and along a second direction orthogonal to the first direction, and dividing the wafer along the first and second grooves.

The method according to this invention for the production of semiconductor chips embraces the fact that each of the positions not conforming to the central lines of the first grooves are, when viewing the substrate in plan view, positions parted by 20 to 100% of the line width (W1) of the first grooves relative to the central lines of the first grooves.

The method according to this invention for the production of semiconductor chips embraces the fact that at the step of forming the second grooves, the second grooves are so formed that obliquely divided chips may assume cut faces having angles in the range of 60 to 85°.

The method according to this invention for the production of semiconductor chips embraces the fact that the method further comprises a step of polishing the substrate side prior to forming the second grooves to adjust a thickness of the substrate in a range of 60 to 100 μm.

The method according to this invention for the production of semiconductor chips embraces the fact that the first grooves are confronted by an electrode-forming surface for forming an electrode for gallium nitride compound semiconductor chips.

The method according to this invention for the production of semiconductor chips embraces the fact that the second grooves are formed by at least one method selected from the group consisting of etching, dicing, pulse laser and scriber.

The method according to this invention for the production of semiconductor chips embraces the fact that the substrate is formed of hexagonal SiC, a hexagonal nitride semiconductor or hexagonal GaN.

This invention also provides semiconductor chips which are obtained by the method for the production of semiconductor chips mentioned above.

This invention contemplates forming the first grooves on the gallium nitride compound semiconductor layer side and the second grooves on the substrate side at mutually unconformable positions, for example, on the substrate regarded as a flat surface, forming the second grooves at positions parted by 20 to 100% of the line width (W1) of the first grooves relative to the central lines of the first grooves and consequently producing semiconductor chips by utilizing the inclination of the cut faces to constitute themselves oblique breakage during the separation of the wafer along the first and second grooves and, therefore, enables even a wafer having a gallium nitride compound semiconductor devoid of cleavability laminated on a substrate devoid of cleavability to be accurately cut in an extremely high yield and further separated into small chips, with the result that the number of chips taken out of one wafer will be increased and the productivity will be enhanced.

### BRIEF DESCRIPTION OF THE DRAWINGS

FIG. 1 is a schematic cross section of a wafer for illustrating the method of this invention for the production of semiconductor chips.

FIG. 2 is a schematic cross section of a wafer for illustrating the method of this invention for the production of semiconductor chips.

FIG. 3 is a diagram illustrating first grooves formed on a nitride semiconductor layer side in one example of this invention.

FIG. 4 is a schematic cross section of a wafer for illustrating the conventional method.

### BEST MODE OF CARRYING OUT THE INVENTION

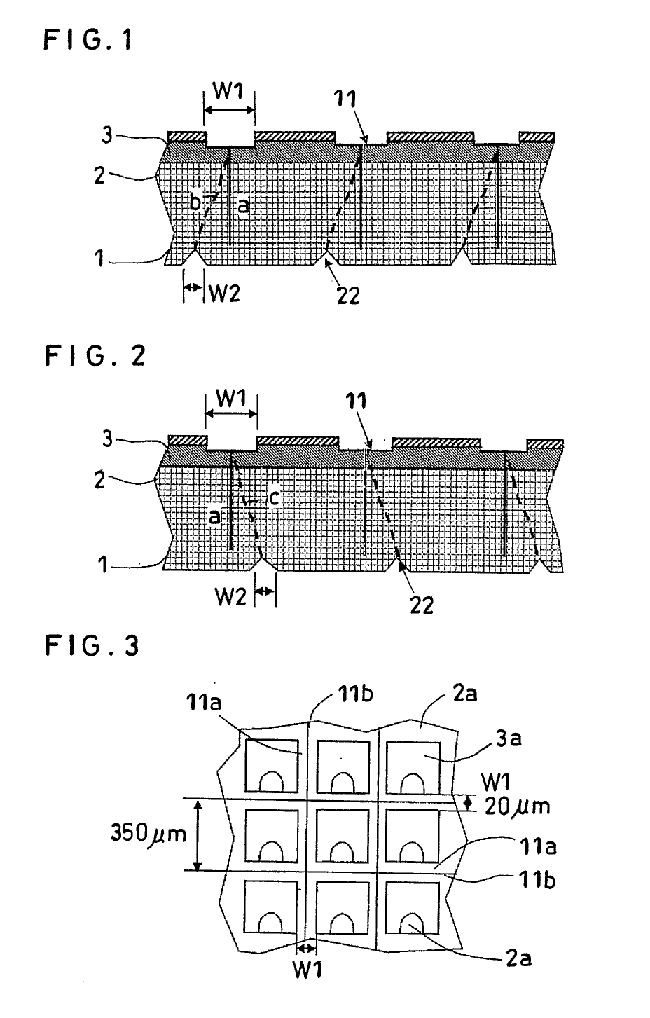

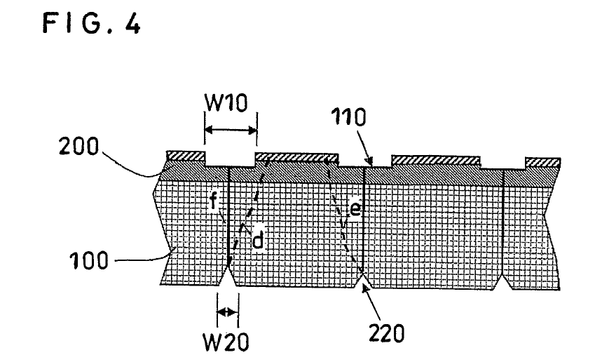

FIG. 1 and FIG. 2 are schematic cross sections of wafers for illustrating the method of this invention for the production of semiconductor chips. Here, the case of separating (dividing) into chips a wafer formed by laminating an n-type gallium nitride compound semiconductor layer (n-type layer) 2 and a p-type gallium nitride compound semiconductor layer (p-type layer) 3 on a sapphire substrate 1 is assumed for the description.

The method of production contemplated by this invention first has first grooves 11 formed linearly in a desired chip shape by etching on the sides of the gallium nitride compound semiconductor layers 2 and 3. The first grooves 11 have a line width of W1 and are formed by etching the p-type layer 3 so as to expose the n-type layer 2.

Next, second grooves 22 are formed on the side of the substrate 1 at the positions not conforming to the central lines of the first grooves 11. For example, the positions are parted by 20 to 100%, preferably 20 to 80%, of the line width (W1) of the first grooves 11 relative to the central lines of the first grooves when viewing the substrate 1 in top view. The second grooves 22 are formed so as to assume a nearly equal or smaller line width (W2) than the line width (W1) of the first grooves 11. On which side of the central lines of the first grooves 11 the second grooves 22 are to be formed may be decided by performing a trial division in advance.

Then, the wafer is divided into pieces of the shape of chips along the first and second grooves 11 and 22. At this time, the wafer is diagonally broken along the broken line b shown in FIG. 1 and the broken line c shown in FIG. 2. The angle of the broken faces (the angle of oblique division of chips) is in the range of 60 to 85° relative to the face of the substrate 1. In this invention, since the second grooves 22 are formed at positions parted from the central lines of the first grooves 11, the breakage falls within the first grooves and the broken faces will not enter into the chips' side regions outside them.

That is, since this invention contemplates producing semiconductor chips by utilizing the inclination of the cut faces constituting themselves oblique breakage during the division of the wafer along the first and second grooves 11 and 22, it enables even a wafer resulting from laminating gallium nitride compound semiconductors 2 and 3 devoid of cleavability on the substrate 1 devoid of cleavability to be accurately cut in an extremely high yield and divided into small chips, with the result that the number of chips taken out of one wafer will be increased and the productivity will be enhanced.

To form the first grooves 11 in the method for producing semiconductor chips, the etching method, such as wet etching or dry etching, is used most preferably. This is because the etching inflicts the least damage on the surfaces and the lateral faces of nitride semiconductors. As the dry etching, techniques, such as reactive ion etching, ion milling, focused beam etching and ECR etching, are available. As the wet etching, mixed acid of sulfuric acid with phosphoric acid, for example, is available. Needless to mention, the prescribed mask designed to impart a necessary shape to the produced chips is formed on the surface of the nitride semiconductor prior to performing the etching thereon.

Then, to form the second grooves 22 on the substrate 1 side, techniques, such as etching, dicing, pulse laser and scriber, are available. Since the second grooves 22 are formed on the substrate 1 side and the edge of a dicer or a scriber does not directly touch the nitride semiconductor layers 2 and 3, this step does not particularly need to discriminate the technique for forming the second grooves. Among other techniques, however, the scriber is used particularly advantageously. This is because the scriber is capable of more easily giving a smaller size to the line width W1 of the first expending slots 11 than the line width W2 of the second grooves and more quickly forming an groove than the etching. It is further at an advantage in decreasing the surface area of the substrate 1 to be shaved off during the division of the wafer as compared with the dicing and consequently enabling more chips to be obtained from one wafer.

Further, it is preferable to polish the substrate 1 side to decrease the thickness thereof prior to the formation of the second grooves 22. The substrate after the polishing has the thickness thereof adjusted to not more than 150 μm and more preferably in a range of 60 to 100 μm. This is because the suppression of the thickness of the substrate results in curtailing the distance of cutting and consequently enhancing the infallibility with which the cutting is made to fall within the first grooves.

Next, one example will be described below with additional reference to FIG. 3.

FIG. 3 is a diagram illustrating first grooves formed on the nitride semiconductor layer side in the example. In this example, a wafer having an n-type GaN layer 2a of a thickness of 5 μm and a p-type GaN layer 3a having a thickness of 1 μm sequentially grown on a sapphire substrate having a thickness of 400 μm and a surface area of the square of 2 inches is prepared. Then, with the C surface of this sapphire substrate as a principle surface, the first and the second grooves are formed along the first direction parallel to the orientation flat (11-20) and the second direction orthogonal to the first direction.

Then, the p-type GaN layer 2a is covered by the photolithographic technique with a mask made of SiO₂ and then subjected to etching to form thereon first grooves 11a in the shape shown in FIG. 3. It is provided that the first grooves 11a have a depth of about 2 μm, a line width W1 of 20 μm and a pitch of 350 μm.

The p-type GaN layer 3a is etched in an approximately semicircular shape at the position confronting the first grooves 11a so as to expose the n-type GaN layer 2a and use it as an electrode-forming surface.

After the first grooves 11a have been formed as described above, the sapphire substrate side of the wafer is polished with a grinding machine and the substrate is lapped and polished to a thickness of 80 μm. By the polishing, the surface of the substrate is specularly uniformized so that the first grooves 11a may be easily discerned from the sapphire substrate.

Then, an adhesive tape is pasted to the p-type GaN layer side and the wafer is pasted to the table of a scriber and immobilized thereto with a vacuum chuck. The table is so constructed as to be movable in the directions of the X axis (bilateral) and the Y axis (lengthwise) and rotatable. After the immobilization, the sapphire substrate is scribed once with the diamond needle of the scriber at a pitch of 350 μM in the direction of X axis, a depth of 5 μm and a line width of 5 μm. The table is turned by 90° and the sapphire substrate is scribed in the same manner in the direction of the Y axis. Thus, scribed lines are inserted so as to delineate chips of the square of 350 μm and effect formation of second grooves. It is provided, however, that the second grooves are formed at positions not conforming to the central lines 11b of the first grooves 11a.

After the scribing is completed, the vacuum chuck is released and the wafer is ripped off the table and cleaved and separated by the pressure exerted from the sapphire substrate side to obtain numerous chips of a surface area of the square of 350 μm from the wafer having a diameter of 2 inches. By selecting the chips free from defective external shape, the yield of chips was not less than 90%.

### COMPARATIVE EXAMPLE

Chips having the surface area of the square of 350 μm were obtained by following the procedure of the example while forming the second grooves on the substrate side at positions conforming to the central lines of the first grooves. The yield of the chips was 60% in this case.

While the preceding description has depicted the substrate 1 as what is formed of sapphire, the substrate may be formed of other material, such as hexagonal SiC, a hexagonal nitride semiconductor or hexagonal GaN, for example.

### INDUSTRIAL APPLICABILITY

Since this invention contemplates producing semiconductor chips by utilizing the inclination of the cut faces constituting themselves oblique breakage during the separation of the wafer along the first and the second grooves, it enables even a wafer having a gallium nitride compound semiconductor devoid of cleavability laminated on a substrate devoid of cleavability to be accurately cut in an extremely high yield and further separated into small chips, with the result that the number of chips taken out of one wafer will be increased and the productivity will be enhanced.

1. A method for the production of gallium nitride compound semiconductor chips from a wafer having gallium nitride compound semiconductor layers laminated on a principal surface of a substrate, comprising:
a step of linearly forming first grooves (11) in a desired chip shape by etching on a side of the gallium nitride compound semiconductor layers (2, 3) of said wafer,
a step of forming second grooves (22) having a nearly equal or smaller line width (W2) than a line width (W1) of the first grooves on a side of the substrate (1) of said wafer at positions not conforming to the central lines of the first grooves, and
a step of dividing said wafer along said first and second grooves into pieces each of a chip shape.

2. A method according to claim 1, wherein said substrate is formed of sapphire, with a C surface of the sapphire substrate as the principal surface, said first and second grooves are formed respectively along a first direction parallel to an orientation flat (11-20) and along a second direction orthogonal to said first direction, and the wafer is divided along the first and second grooves.

3. A method according to claim 1, wherein the positions not confirming to the central lines of said first grooves are, when viewing the substrate in plan view, positions parted by 20 to 100% of the line width (W1) of the first grooves relative to the central lines of the first grooves.

4. A method according to claim 1, wherein at the step of forming said second grooves, the second grooves are formed so that the obliquely divided chips assume cut faces having angles in the range of 60 to 85°.

5. A method according to claim 1, further comprising a step of polishing the substrate side prior to forming the second grooves to adjust a thickness of the substrate in a range of 60 to 100 μm.

6. A method according to claim 1, wherein said first grooves are confronted by an electrode-forming surface for forming an electrode for gallium nitride compound semiconductor chips.

7. A method according to claim 1; wherein said second grooves are formed by at least one method selected from the group consisting of etching, dicing, pulse laser and scriber.

8. A method according to claim 1, wherein said substrate is formed of hexagonal SiC.

9. A method according to claim 1, wherein said substrate is formed of a hexagonal nitride semiconductor.

10. A method according to claim 1, wherein said substrate is formed of hexagonal GaN.

11. Semiconductor chips obtained by the method for the production of semiconductor chips set forth in claim 1.
